(19) United States
(12) Patent Application Publication
(10) Pub. No.: US 2026/0253774 A1
(43) Pub. Date: Aug. 27, 2026

(54) SUPERCONDUCTING COIL

(71) Applicant: SUMITOMO HEAVY INDUSTRIES, LTD., Tokyo (JP)

(72) Inventor: Fumiaki KAMISAKI, Yokosuka-shi (JP)

(21) Appl. No.: 19/649,269

(22) Filed: Apr. 16, 2026

Related U.S. Application Data
(63) Continuation of application No. PCT/JP2025/000948, filed on Jan. 15, 2025.

(30) Foreign Application Priority Data
Feb. 6, 2024 (JP) 2024-016567

(51) Int. Cl. H01F 6/06; H10N 60/83

(52) U.S. Cl. CPC H01F 6/06; H10N 60/83

(57) ABSTRACT

A superconducting coil includes a winding frame, a coil body including a plurality of layers of a superconducting wire material stacked on the winding frame, each of the layers having a plurality of turns of the superconducting wire material, a first fixed wall provided on the winding frame to be adjacent to a first turn of the plurality of turns in at least a first layer of the plurality of layers, and a first impregnation material containing a photocurable resin material and impregnated in at least a part of a space between the first turn and the first fixed wall.

### CROSS-REFERENCE TO RELATED APPLICATIONS

This is a bypass continuation of International PCT Application No. PCT/JP2025/000948, filed on January 15, 2025, which claims priority to Japanese Patent Application No. 2024-016567, filed on February 6, 2024, which are incorporated by reference herein in their entirety.

### BACKGROUND

### TECHNICAL FIELD

A certain embodiment of the present invention relates to a superconducting coil.

### DESCRIPTION OF RELATED ART

A superconducting coil is formed by winding a superconducting wire material. The wound superconducting wire material is impregnated with a synthetic resin material in order to fix the superconducting wire material and to improve mechanical strength of the superconducting coil.

### SUMMARY

One or more embodiments provide a superconducting coil including a winding frame, a coil body including a plurality of layers of a superconducting wire material stacked on the winding frame, each of the layers having a plurality of turns of the superconducting wire material, a first fixed wall provided on the winding frame to be adjacent to a winding-start turn of the plurality of turns in at least a first layer of the plurality of layers, and a first impregnation material containing a photocurable resin material and impregnated in at least a part of a space between the winding-start turn and the first fixed wall.

### BRIEF DESCRIPTION OF THE DRAWINGS

FIG. 1 is a view schematically showing a superconducting coil, according to an embodiment.

FIG. 2 is a view schematically showing a manufacturing process of the superconducting coil, according to the embodiment.

FIGS. 3A and 3B are views schematically showing a part of a manufacturing process of a superconducting coil, according to a comparative example.

### DETAILED DESCRIPTION

In general, a thermosetting resin is used for the impregnation of the wound superconducting wire material. A thermosetting process may take, for example, several hours to several tens of hours or more. Therefore, it takes a long time to manufacture the superconducting coil.

It is desirable to improve workability in manufacturing a superconducting coil.

Hereinafter, an embodiment for carrying out the present invention will be described in detail with reference to the drawings. In the description and the drawings, the same or equivalent components, members, and processes will be denoted by the same reference numerals, and overlapping descriptions will be omitted as appropriate. The scale or shape of each part that is shown in the drawings is conveniently set for ease of description and is not limitedly interpreted unless otherwise specified. The embodiment is merely an example and does not limit the scope of the present invention in any way. All of the features described in the embodiments and combinations thereof are not necessarily essential to the invention.

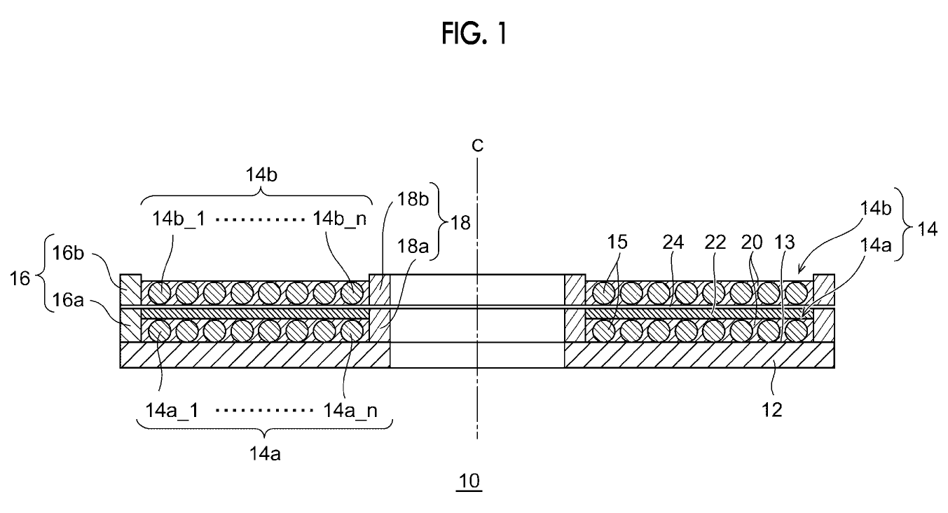

FIG. 1 is a view schematically showing a superconducting coil 10 according to the embodiment. FIG. 1 schematically shows a cross section of the superconducting coil 10 in a plane including a center line C of the superconducting coil 10.

The superconducting coil 10 is configured to generate a strong magnetic field by being energized in a state of being cooled to a cryogenic temperature equal to or lower than a superconducting transition temperature. The superconducting coil 10 may be a known superconducting coil, and may be, for example, a low-temperature superconducting coil. Alternatively, the superconducting coil 10 may be a high-temperature superconducting coil. The superconducting coil 10 is mounted on a high magnetic field utilization device as a magnetic field source of a high energy physics system such as an NMR system, an MRI system, an accelerator such as a cyclotron, or a nuclear fusion system, or another high magnetic field utilization device (not shown), and can generate a high magnetic field required for the device.

The superconducting coil 10 includes a winding frame 12, a coil body 14, a first fixed wall 16, and a second fixed wall 18.

The winding frame 12 supports the coil body 14. The winding frame 12 may be formed of, for example, a non-magnetic metallic material such as stainless steel or an aluminum alloy. Alternatively, the winding frame 12 may be formed of, for example, a fiber-reinforced plastic (FRP) such as a glass fiber reinforced plastic (GFRP), or other appropriate materials.

The winding frame 12 includes an annular winding surface 13. The winding surface 13 is formed on the winding frame 12 along a virtual plane intersecting the center line C. For example, the winding surface 13 may be formed on the winding frame 12 along a plane perpendicular to the center line C. The winding surface 13 may be formed on the winding frame 12 along a curved surface intersecting the center line C. The center line C may be parallel to a direction of gravity, that is, a vertical direction, and an upper surface of the winding frame 12 may be used as the winding surface 13. When viewed from the direction of the center line C, the winding surface 13 can have various planar shapes such as a circular shape, an oval shape such as a racetrack shape, or a rectangular shape.

The coil body 14 is formed by winding a superconducting wire material 15. The coil body 14 includes a plurality of layers of the superconducting wire material 15 stacked on the winding frame 12. Each layer has a plurality of turns of the superconducting wire material 15.

As an example, the coil body 14 may be a so-called multilayer pancake coil. In this case, the plurality of turns in each layer are wound in a spiral shape around the center line C. In other words, the plurality of turns in each layer are wound around the center line C such that a distance from the center line C to each turn is different for each turn. The coil body 14 may have a cylindrical shape. Alternatively, the coil body 14 may have a saddle shape.

In the shown example, the coil body 14 has a first layer 14a and a second layer 14b. The first layer 14a of the coil body 14 is stacked on the winding surface 13 of the winding frame 12. The second layer 14b of the coil body 14 is stacked on the first layer 14a.

The first layer 14a has a first turn 14a_1 to an n-th turn 14a_n (here, n may be any natural number greater than 1). The first turn 14a_1 is a winding-start turn of the first layer 14a, and the n-th turn 14a_n is a winding-end turn of the first layer 14a. In this example, the first layer 14a is wound around the center line C along the winding surface 13 such that the first turn 14a_1 is located on an outer peripheral side (that is, a side far from the center line C) of the coil body 14 and the n-th turn 14a_n is located on an inner peripheral side (that is, a side close to the center line C) of the coil body 14. The winding may be performed in the opposite manner, and the first layer 14a may be wound around the center line C such that the first turn 14a_1 is located on the inner peripheral side and the n-th turn 14a_n is located on the outer peripheral side.

The second layer 14b has a first turn 14b_1 at the start of winding to an n-th turn 14b_n at the end of winding. In this example, unlike the first layer 14a, the second layer 14b is wound around the center line C along the winding surface 13 such that the first turn 14b_1 is located on the inner peripheral side of the coil body 14 and the n-th turn 14b_n is located on the outer peripheral side of the coil body 14. Therefore, the first turn 14b_1 of the second layer 14b is located on the n-th turn 14a_n of the first layer 14a. In another example, the second layer 14b may be wound such that the first turn 14b_1 of the second layer 14b is located above the first turn 14a_1 of the first layer 14a.

Here, for simplicity, a case where the coil body 14 has two layers of the first layer 14a and the second layer 14b is described as an example, but the coil body 14 may have at least one additional layer stacked on the second layer 14b. The coil body 14 may have at least 10 layers (for example, several tens of layers). In addition, one layer of the coil body 14 may have at least 10 turns (for example, several tens of turns).

The superconducting wire material 15 may be a non-tape-shaped superconducting wire material. For example, the superconducting wire material 15 may be a round wire or a rectangular wire (for example, a flat rectangular wire). The superconducting wire material 15 includes a superconductor. In a case where the superconducting coil 10 is a low-temperature superconducting coil, the superconducting wire material 15 may include a superconductor formed of a superconducting material such as a niobium-titanium alloy (NbTi) or a niobium-tin alloy (Nb₃Sn). In a case where the superconducting coil 10 is a high-temperature superconducting coil, the superconducting wire material 15 may include a superconductor formed of magnesium diboride, a bismuth-based superconductor, a copper oxide superconductor, or another high-temperature superconducting material, for example.

The first fixed wall 16 is provided on the winding frame 12 to be adjacent to the winding-start turn (first turn 14a_1) of the plurality of turns in at least the first layer 14a of the plurality of layers of the coil body 14. In this example, since the first turn 14a_1 of the first layer 14a is located on the outer peripheral side of the coil body 14, the first fixed wall 16 is adjacent to the outer peripheral side of the coil body 14.

The first fixed wall 16 extends upward from the winding frame 12 in a stacking direction of the coil body 14 (that is, the direction of the center line C), and is also adjacent to the second layer 14b. In this example, since the winding-end turn (n-th turn 14b_n) of the second layer 14b is located above the first turn 14a_1 of the first layer 14a, the first fixed wall 16 is adjacent to the n-th turn 14b_n of the second layer 14b.

In the present embodiment, the first fixed wall 16 has a structure divided for each layer of the coil body 14. The first fixed wall 16 includes a first wall member 16a adjacent to the first layer 14a of the coil body 14, and a second wall member 16b attached to the first wall member 16a and adjacent to the second layer 14b of the coil body 14.

A height of each wall member (for example, the first wall member 16a or the second wall member 16b) constituting the first fixed wall 16 corresponds to a height of the superconducting wire material 15. For example, the height of each wall member may be equal to or greater than the height of the superconducting wire material 15. The height of each wall member may be 1.1 times or less the height of the superconducting wire material 15. Here, the height of the wall member refers to the dimension of the wall member in the direction of the center line C. The height of the superconducting wire material 15 refers to the dimension of the superconducting wire material 15 in the direction of the center line C, for example, a diameter of the superconducting wire material 15.

The second fixed wall 18 is provided on the winding frame 12 to be adjacent to the winding-end turn (n-th turn 14a_n) of the plurality of turns in the first layer 14a of the coil body 14. In this example, since the n-th turn 14a_n of the first layer 14a is located on the inner peripheral side of the coil body 14, the second fixed wall 18 is adjacent to the inner peripheral side of the coil body 14.

The second fixed wall 18 extends upward from the winding frame 12 in the stacking direction of the coil body 14 (that is, the direction of the center line C), and is also adjacent to the second layer 14b. In this example, since the winding-start turn (first turn 14b_1) of the second layer 14b is located above the n-th turn 14a_n of the first layer 14a, the second fixed wall 18 is adjacent to the first turn 14b_1 of the second layer 14b. As described above, the winding-end turn (n-th turn 14b_n) of the second layer 14b may be located above the n-th turn 14a_n of the first layer 14a, and in this case, the second fixed wall 18 may be adjacent to the n-th turn 14b_n of the second layer 14b.

Similar to the first fixed wall 16, the second fixed wall 18 has a structure divided for each layer of the coil body 14. The second fixed wall 18 includes a first wall member 18a adjacent to the first layer 14a of the coil body 14, and a second wall member 18b attached to the first wall member 18a and adjacent to the second layer 14b of the coil body 14.

A height of each wall member (for example, the first wall member 18a or the second wall member 18b) constituting the second fixed wall 18 corresponds to the height of the superconducting wire material 15. For example, the height of each wall member may be equal to or greater than the height of the superconducting wire material 15. The height of each wall member may be 1.1 times or less the height of the superconducting wire material 15. In addition, the height of each wall member constituting the second fixed wall 18 may be equal to the height of each wall member constituting the first fixed wall 16.

In a case where the coil body 14 has at least one additional layer stacked on the second layer 14b, the first fixed wall 16 may include at least one additional wall member attached to the second wall member 16b. Similarly, the second fixed wall 18 may include at least one additional wall member attached to the second wall member 18b. Each of the at least one additional wall member may be adjacent to a corresponding layer of the at least one additional layer of the coil body 14.

The first fixed wall 16 may be provided on the winding frame 12 to be adjacent to the coil body 14 over the entire circumference of the coil body 14 around the center line C. In this case, the first fixed wall 16 may be continuous along the circumference of the coil body 14. Alternatively, the first fixed wall 16 may be divided along the circumference of the coil body 14. For example, the first fixed wall 16 may include a plurality of wall pieces each adjacent to the coil body 14, and these wall pieces may be arranged without gaps along the circumference of the coil body 14. Similarly, the second fixed wall 18 may be provided on the winding frame 12 to be adjacent to the coil body 14 over the entire circumference of the coil body 14 around the center line C.

Alternatively, the first fixed wall 16 may be provided on the winding frame 12 to be adjacent to the coil body 14 in a part of the entire circumference of the coil body 14. For example, the first fixed wall 16 may include a plurality of wall pieces each adjacent to the coil body 14, and these wall pieces may be arranged at intervals (for example, at equal intervals) along the circumference of the coil body 14. Similarly, the second fixed wall 18 may be provided on the winding frame 12 to be adjacent to the coil body 14 in a part of the entire circumference of the coil body 14.

The first fixed wall 16 and the second fixed wall 18 may be formed of the same material as the winding frame 12, or may be formed of a material different from the winding frame 12. Therefore, the fixed wall may be formed of, for example, a non-magnetic metallic material such as stainless steel or an aluminum alloy. Alternatively, the fixed wall may be formed of, for example, a fiber-reinforced plastic (FRP) such as glass fiber reinforced plastic (GFRP), or other appropriate materials.

The first fixed wall 16 and the second fixed wall 18 may be mechanically fixed to the winding frame 12 using a fastening member such as a bolt or a screw. Alternatively, the first fixed wall 16 and the second fixed wall 18 may be fixed to the winding frame 12 by adhesion or other appropriate methods. In addition, the fixing of the wall members constituting the fixed wall may also be performed mechanically or by other appropriate methods.

In addition, the coil body 14 includes a first impregnation material 20, a second impregnation material 22, and a sheet material 24.

The first impregnation material 20 contains a photocurable resin material, and in this example, is formed of the photocurable resin material. The photocurable resin material may be, for example, a known ultraviolet-curable resin material such as an acrylic ultraviolet-curable resin material or an epoxy-based ultraviolet-curable resin material. Alternatively, the photocurable resin material may be a visible light-curable resin material.

The first impregnation material 20 is impregnated in at least a part of a space between the coil body 14 and the first fixed wall 16. In the shown example, the first impregnation material 20 is impregnated in at least a part of a space between the first turn 14a_1 of the first layer 14a and the first fixed wall 16, and at least a part of a space between the n-th turn 14b_n of the second layer 14b and the first fixed wall 16. The first impregnation material 20 may be impregnated over the entire circumference of the coil body 14 along the first fixed wall 16, or may be impregnated in a part (or a plurality of parts) of the entire circumference of the coil body 14 along the first fixed wall 16. In this way, the coil body 14 is fixed to the first fixed wall 16 by the first impregnation material 20.

In addition, the first impregnation material 20 is impregnated in at least a part of a space between the coil body 14 and the second fixed wall 18. In the shown example, the first impregnation material 20 is impregnated in at least a part of a space between the n-th turn 14a_n of the first layer 14a and the second fixed wall 18, and at least a part of a space between the first turn 14b_1 of the second layer 14b and the second fixed wall 18. The first impregnation material 20 may be impregnated over the entire circumference of the coil body 14 along the second fixed wall 18, or may be impregnated in a part (or a plurality of parts) of the entire circumference of the coil body 14 along the second fixed wall 18. In this way, the coil body 14 is fixed to the second fixed wall 18 by the first impregnation material 20.

The first impregnation material 20 is also impregnated in at least a part of a space between the first layer 14a of the coil body 14 and the winding surface 13 of the winding frame 12. In this way, the coil body 14 is fixed to the winding frame 12 by the first impregnation material 20. In addition, in order to fix the first layer 14a and the second layer 14b of the coil body 14, the first impregnation material 20 is impregnated in at least a part of a space between the first layer 14a and the second layer 14b of the coil body 14. In the shown example, since the sheet material 24 is provided between the first layer 14a and the second layer 14b, the first impregnation material 20 is impregnated in at least a part of a space between the sheet material 24 and the second layer 14b.

The second impregnation material 22 is impregnated between two adjacent layers in the plurality of layers of the coil body 14. The second impregnation material 22 is impregnated in at least a part of a space between the first layer 14a and the second layer 14b of the coil body 14. In the shown example, since the sheet material 24 is provided between the first layer 14a and the second layer 14b, the second impregnation material 22 is impregnated in at least a part of a space between the first layer 14a and the sheet material 24. The second impregnation material 22 may be, for example, a thermosetting resin material, an adhesive, or another appropriate synthetic resin material. In this way, two adjacent layers of the coil body 14 are fixed to each other by the second impregnation material 22.

The sheet material 24 is provided between two adjacent layers in the plurality of layers of the coil body 14 to partition the two layers. The sheet material 24 may be formed of, for example, a fiber-reinforced plastic (FRP) such as a glass fiber reinforced plastic (GFRP), or another appropriate insulating material. As shown, in a case where the first fixed wall 16 and the second fixed wall 18 have a divided structure, the sheet material 24 may be sandwiched between two stacked wall members (for example, the first wall member 16a and the second wall member 16b).

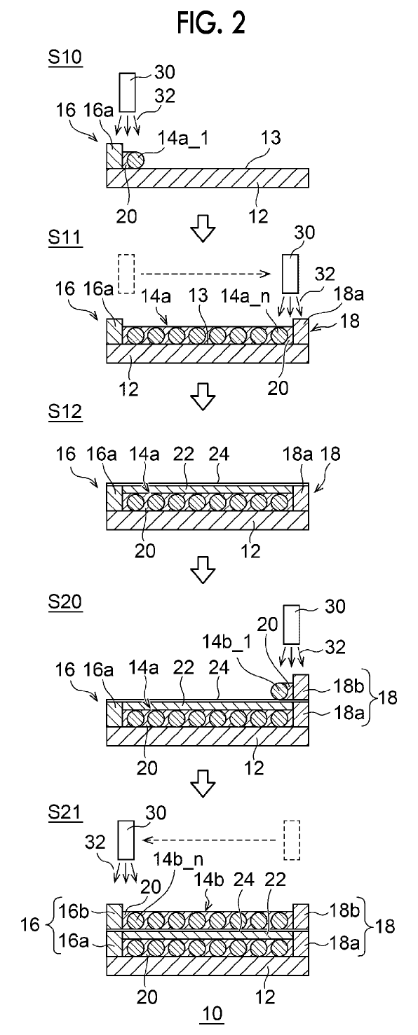

FIG. 2 is a view schematically showing a manufacturing process of the superconducting coil 10 according to the embodiment. In this manufacturing process, first, as shown in S10 of FIG. 2, the winding frame 12 is prepared, and the first wall member 16a of the first fixed wall 16 is installed on the winding frame 12. The first turn 14a_1 of the first layer 14a of the coil body 14 is wound on the winding surface 13 of the winding frame 12 to be adjacent to the first wall member 16a. The first impregnation material 20 is applied between the first turn 14a_1 of the first layer 14a and the first wall member 16a.

Then, a light source 30 that can emit light 32 for curing the photocurable resin material contained in the first impregnation material 20 is prepared. The light source 30 is disposed above the first wall member 16a and the first turn 14a_1 of the first layer 14a to irradiate the light 32 perpendicularly toward the winding surface 13. The light 32 is irradiated downward from the light source 30 toward the first wall member 16a and the first turn 14a_1. As a result, the first impregnation material 20 between the first wall member 16a and the first turn 14a_1 is cured.

Subsequently, as shown in S11 of FIG. 2, the first layer 14a of the coil body 14 is wound up to the n-th turn 14a_n. The first wall member 18a of the second fixed wall 18 is installed on the winding frame 12 to be adjacent to the n-th turn 14a_n. The first wall member 18a of the second fixed wall 18 may be installed on the winding frame 12 in advance before the n-th turn 14a_n is wound (for example, together with the first wall member 16a of the first fixed wall 16). The first impregnation material 20 is applied to each turn of the first layer 14a.

As schematically shown by a broken line arrow in S11 of FIG. 2, the light source 30 irradiates the light 32 in order up to the n-th turn 14a_n while moving above the first layer 14a. The light source 30 irradiates each turn with the light 32 in the same direction. That is, the light source 30 perpendicularly irradiates each turn of the first layer 14a with the light 32 from above. The first impregnation material 20 is cured between the first layer 14a and the winding surface 13 by the irradiation with the light 32. In addition, the first impregnation material 20 is cured between the first wall member 18a of the second fixed wall 18 and the n-th turn 14a_n. In this way, the first layer 14a is fixed to the winding frame 12, the first fixed wall 16, and the second fixed wall 18.

As shown in S12 of FIG. 2, the second impregnation material 22 is applied onto the first layer 14a to cover the first layer 14a. The second impregnation material 22 is applied in accordance with the height of the first wall member 16a of the first fixed wall 16 and the height of the first wall member 18a of the second fixed wall 18. Then, the sheet material 24 is laid on the second impregnation material 22 and the fixed walls. The first layer 14a is completely fixed to the winding frame 12 and the fixed walls by curing the second impregnation material 22.

Next, as shown in S20 of FIG. 2, the second wall member 18b of the second fixed wall 18 is installed on the first wall member 18a. The sheet material 24 is interposed between the first wall member 18a and the second wall member 18b. The first turn 14b_1 of the second layer 14b of the coil body 14 is wound on the first layer 14a to be adjacent to the second wall member 18b. The first impregnation material 20 is applied between the first turn 14b_1 of the second layer 14b and the second wall member 18b. Then, the light source 30 perpendicularly irradiates the first turn 14b_1 of the second layer 14b with the light 32 from above. As a result, the first impregnation material 20 between the second wall member 18b and the first turn 14b_1 is cured.

Subsequently, as shown in S21 of FIG. 2, the second layer 14b of the coil body 14 is wound up to the n-th turn 14b_n. The second wall member 16b of the first fixed wall 16 is installed on the first wall member 16a to be adjacent to the n-th turn 14b_n. The sheet material 24 is interposed between the first wall member 16a and the second wall member 16b. The first impregnation material 20 is applied to each turn of the second layer 14b. As schematically shown by a broken line arrow, the light source 30 irradiates the light 32 in order up to the n-th turn 14b_n while moving above the second layer 14b. The light source 30 irradiates each turn with the light 32 in the same direction. That is, the light source 30 perpendicularly irradiates each turn of the second layer 14b with the light 32 from above. By the irradiation with the light 32, the first impregnation material 20 is cured between the second layer 14b and the sheet material 24. In addition, the first impregnation material 20 is cured between the second wall member 16b of the first fixed wall 16 and the n-th turn 14b_n. In this way, the second layer 14b is fixed to the first layer 14a, the first fixed wall 16, and the second fixed wall 18.

The second impregnation material 22 may be applied to the second layer 14b, and the sheet material 24 may be laid thereon. In a case where the coil body 14 has additional layers, a large number of layers can be stacked by repeating the processing of S10 to S12 described above.

As described at the beginning of the present specification, in general, a thermosetting resin is used as an impregnation material in an existing superconducting coil. Since the process of the thermosetting may take, for example, several hours to several tens of hours or more, it takes a long time to manufacture the superconducting coil. In particular, in an impregnation method in which a resin material is applied while the superconducting wire material is wound around the winding frame, the method being a so-called “coat-and-wind” method, a thermosetting resin having a relatively long curing time may be intentionally used among thermosetting resins in order to avoid thermal curing of the resin material interfering with work of winding the superconducting wire material around the winding frame. In this case, the thermosetting process takes even longer.

On the other hand, in the superconducting coil 10 according to the embodiment, a photocurable resin material is used as the first impregnation material 20. The photocurable resin material typically requires only several minutes at most for the photocuring process. By using the first impregnation material 20, the superconducting wire material 15 can be quickly fixed. In addition, as the second impregnation material 22 that is applied after being fixed in this way, a second impregnation material having a relatively short curing time can be used. Therefore, the manufacturing of the superconducting coil 10 according to the embodiment can achieve a significant reduction in time compared to the existing superconducting coil.

In addition, it is easy to selectively apply the irradiation with the light 32 to a local region of the coil body 14. In addition, it is also easy to irradiate the superconducting wire material 15 with the light 32 at any point in time during the winding of the superconducting wire material 15 around the winding frame 12. On the other hand, the degree of freedom is small in the thermosetting process.

The photocuring process can be adapted to the manufacturing of a coil having a more complicated shape, such as a saddle-shaped coil, due to the high degree of freedom in the irradiation location and the irradiation timing. Unlike a circular coil, in the coil having a complicated shape, there may be a manufacturing difficulty in that, during a process of winding the wire material around the winding frame, the wire materials may deviate from each other due to the tension acting on the wire materials, making it difficult to wind the wire material while maintaining a desired coil shape. However, according to the embodiment, by curing the first impregnation material 20 at a specific local location at a desired timing in the winding process of the wire material, it is possible to temporarily fix the wire material in a spot-like manner during the winding and to wind the wire material while maintaining a desired coil shape. Therefore, the superconducting coil 10 according to the embodiment is advantageous in a coil winding having a complicated shape.

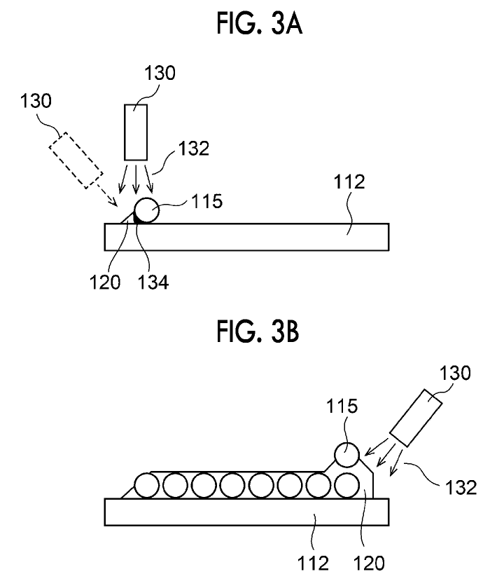

FIGS. 3A and 3B are views schematically showing a part of a manufacturing process of a superconducting coil, according to a comparative example. In this comparative example, a winding frame 112 is not provided with a fixed wall. In this case, the present inventors have found that the curing conditions of a first impregnation material 120 are different between the first turn and the second and subsequent turns of a superconducting wire material 115.

In the comparative example, in order to fix the first turn of the superconducting wire material 115 to the winding frame 112 located therebelow, it is necessary to cure the first impregnation material 120 applied between the first turn of the superconducting wire material 115 and the winding frame 112 (that is, below the first turn). When light 132 from a light source 130 is perpendicularly irradiated from above, a shadowed portion 134 is generated below the first turn due to the first turn in the first impregnation material 120, as schematically shown by a black portion in FIG. 3A. The light 132 is less likely to reach the portion 134 of the first impregnation material 120, and thus the first impregnation material 120 is less likely to be cured. That is, the adhesion of the first turn to the winding frame 112 by the first impregnation material 120 may be insufficient.

As one method of dealing with this problem, it is conceivable to change an irradiating direction of the light source 130 as schematically shown by a broken line in FIG. 3A. By irradiating the first turn obliquely instead of perpendicularly irradiating the first turn with the light 132 from the light source 130, the light 132 can be made to effectively reach the portion 134 below the first turn, and the first impregnation material 120 in the portion 134 can be effectively cured.

However, such oblique irradiation is not effective for adhesion of the second and subsequent turns. The first turn is already present adjacent to the second turn. Therefore, in the oblique irradiation, the light is less likely to reach the first impregnation material 120 between the adjacent turns. In this case, the adhesion of the second turn may be insufficient.

In order to avoid this, it is considered desirable to change the irradiating direction again and perpendicularly irradiate the light 132 from above in the second and subsequent turns. As a result, the light 132 can be made to effectively reach the first impregnation material 120 between the adjacent turns, and the first impregnation material 120 can be effectively cured. In addition, it is considered desirable to irradiate the n-th turn at the end of winding and the first turn of an upper layer thereabove from an oblique direction opposite to that for the first turn as shown in FIG. 3B. However, since such a change in the irradiating direction from the light source 130 for each turn complicates the irradiation work, there is a concern that the workability may be reduced.

On the other hand, according to the embodiment, the first fixed wall 16 is provided adjacent to the first turn 14a_1 of the first layer 14a. The first fixed wall 16 may be regarded, so to speak, as a wall that simulates the superconducting wire material 15. When the light 32 is perpendicularly irradiated from the light source 30 onto each turn, the positional relationship between the light source 30 and the first impregnation material 20 located between the first turn 14a_1 and the first fixed wall 16 is the same as the positional relationship between the light source 30 and the first impregnation material 20 located between the first turn 14a_1 and the adjacent second turn. The curing conditions between the first turn 14a_1 and the first fixed wall 16 can be made the same as the curing conditions between the first turn 14a_1 and the second turn. The adhesion of the first turn 14a_1 can be improved, and the adhesion can be made uniform between the first turn 14a_1 and the other turns.

In addition, according to the embodiment, the second fixed wall 18 is provided adjacent to the n-th turn 14a_n of the first layer 14a. For the same reason, the adhesion of the n-th turn 14a_n can be improved, and the adhesion can be made uniform between the n-th turn 14a_n and the other turns. The first fixed wall 16 and the second fixed wall 18 can also make the adhesion uniform for each turn in the layers after the second layer 14b.

In order to manufacture the superconducting coil 10 as designed, it is desirable that the second impregnation material 22 is applied to form a flat surface as a base for the layer stacked thereon. As in the comparative example, in a case where there is no fixed wall, the flatness of the second impregnation material 22 depends on the skill of the worker, and variations may occur.

On the other hand, according to the embodiment, the second impregnation material 22 can be applied in accordance with the heights of the first fixed wall 16 and the second fixed wall 18. In a case where these fixed walls are divided for each layer of the coil body 14, for example, in the first layer 14a, the second impregnation material 22 is applied in accordance with the heights of the first wall member 16a of the first fixed wall 16 and the first wall member 18a of the second fixed wall 18. Therefore, the second impregnation material 22 can be easily applied in a flat manner regardless of the skill of the worker. In addition, the sheet material 24 is laid on the flattened second impregnation material 22, and the next layer of the coil body 14 is formed thereon. This also helps to flatten the next layer. Therefore, according to the embodiment, the workability in the manufacturing of the superconducting coil 10 can be improved.

The present invention has been described hereinbefore based on the examples. The present invention is not limited to the above-described embodiment, and various design changes are possible, and it will be understood by those skilled in the art that various modification examples are possible and such modification examples also fall within the scope of the present invention. Various features described in relation to a certain embodiment are also applicable to other embodiments. A new embodiment resulting from combination will have the effects of each of the embodiments that are combined.

The coil body 14 of the superconducting coil 10 can have various shapes. For example, the coil body 14 may be a cylindrical coil body formed by aligned multilayer winding. In this case, the winding frame 12 may have a cylindrical winding surface 13 centered on the center line C.

In the above-described embodiment, a case where the first fixed wall 16 and the second fixed wall 18 are prepared as separate components from the winding frame 12 and are attached to the winding frame 12 has been described as an example, but the present invention is not limited thereto. The first fixed wall 16 (and/or the second fixed wall 18) may be integrated with the winding frame 12.

In the above-described embodiment, a case where the first impregnation material 20 is made of a photocurable resin material has been described as an example, but the first impregnation material 20 may contain other materials together with the photocurable resin material. For example, the first impregnation material 20 may be a mixture of a photocurable resin material and another synthetic resin material such as a thermosetting resin material or a thermoplastic resin material. In this case, the first impregnation material 20 may be cured by using both light irradiation and heating on the coil body 14.

In addition, the second impregnation material 22 may contain a photocurable resin material. The second impregnation material 22 may be the same material as the first impregnation material 20.

Although the present invention has been described using specific words and phrases based on the embodiment, the embodiment merely shows one aspect of the principle and application of the present invention, and many modification examples and changes in disposition are allowed without departing from the concept of the present invention specified in the claims.

The present invention can be used in the field of superconducting coils.

It should be understood that the invention is not limited to the above-described embodiment, but may be modified into various forms on the basis of the spirit of the invention. Additionally, the modifications are included in the scope of the invention.

What is claimed is:

1. A superconducting coil comprising: a winding frame; a coil body including a plurality of layers of a superconducting wire material stacked on the winding frame, each of the layers having a plurality of turns of the superconducting wire material; a first fixed wall provided on the winding frame to be adjacent to a winding-start turn of the plurality of turns in at least a first layer of the plurality of layers; and a first impregnation material containing a photocurable resin material and impregnated in at least a part of a space between the winding-start turn and the first fixed wall.

2. The superconducting coil according to claim 1,
wherein the first fixed wall is also adjacent to a second layer stacked on the first layer of the plurality of layers, and the first impregnation material is impregnated in at least a part of a space between the second layer and the first fixed wall.

3. The superconducting coil according to claim 2, wherein the first fixed wall includes a first wall member adjacent to the first layer, and a second wall member attached to the first wall member and adjacent to the second layer.

4. The superconducting coil according to claim 3, wherein the first fixed wall is provided to be adjacent to the coil body over an entire circumference of the coil body.

5. The superconducting coil according to claim 1, wherein the coil body includes a sheet material between two adjacent layers of the plurality of layers.

6. The superconducting coil according to claim 5, wherein the sheet material is laid on a second impregnation material impregnated between the two adjacent layers.

7. The superconducting coil according to claim 1, wherein the coil body includes a second impregnation material between two adjacent layers of the plurality of layers.

8. The superconducting coil according to claim 7, wherein the second impregnation material forms a flat surface on which an upper layer of the two adjacent layers is stacked on a lower layer of the two adjacent layers.

9. The superconducting coil according to claim 8, wherein the second impregnation material is applied to cover an upper surface of the lower layer, and the upper layer is stacked thereon.

10. The superconducting coil according to claim 1, further comprising: a second fixed wall provided on the winding frame to be adjacent to a winding-end turn of the plurality of turns in the first layer, wherein the first impregnation material is impregnated in at least a part of a space between the winding-end turn and the second fixed wall.

11. The superconducting coil according to claim 10, wherein a height of each wall member constituting the first fixed wall and the second fixed wall is 1.1 times or less a height of the superconducting wire material.
